(19) United States
(12) Patent Application Publication
(10) Pub. No.: US 2025/0226269 A1
(43) Pub. Date: Jul. 10, 2025

(54) TEST PAD STRUCTURE AND METHOD OF MANUFACTURING AND OPERATING THE SAME

(71) Applicant: TAIWAN SEMICONDUCTOR MANUFACTURING COMPANY LTD., HSINCHU (TW)

(72) Inventors: MING-CHUNG WU, HSINCHU (TW); CHIH-HSUAN TAI, TAIPEI CITY (TW); HSIANG-TAI LU, HSINCHU COUNTY (TW)

(21) Appl. No.: 18/404,932

(22) Filed: Jan. 5, 2024

(51) Int. Cl. H01L 21/66; G01R 31/28; H01L 23/00

(52) U.S. Cl. CPC H01L 22/32; G01R 31/2884; H01L 22/14; H01L 24/03; H01L 24/05; H01L 24/06; H01L 24/11; H01L 24/13; H01L 24/14; H01L 24/16; H01L 24/81; H01L 2224/0392; H01L 2224/05557; H01L 2224/05567; H01L 2224/05624; H01L 2224/05647; H01L 2224/06131; H01L 2224/06132; H01L 2224/06515; H01L 2224/119; H01L 2224/13021; H01L 2224/13083; H01L 2224/13084; H01L 2224/13147; H01L 2224/13155; H01L 2224/14131; H01L 2224/14132; H01L 2224/14515; H01L 2224/16145; H01L 2224/81815

(57) ABSTRACT

A method includes: forming an interconnect structure over a first substrate, the interconnect structure including a top metal layer including a conductive line; depositing a pad structure over the first conductive line; depositing a first bump structure a to cover the pad structure; performing a testing operation on at least one of the pad structure and the first bump structure to leave a probing mark on an upper surface of at least one of the pad structure and the first bump structure; and in response to a testing result of the testing operation as complying with a testing performance, performing an operation to recover the upper surface through eliminating the probing mark.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, the existing testing structure and method may not be suitable for the bumps with a reduced bump area. As a result, an improved pad structure and testing method for the shrunk testing pads is desirable.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1A illustrates a cross-sectional view of a semiconductor device, in accordance with some embodiments of the present disclosure.

FIG. 1B illustrates top views of a signal pad unit or a testing pad unit of the semiconductor device shown in FIG. 1A, in accordance with some embodiments of the present disclosure.

FIG. 2 illustrates a cross-sectional view of a semiconductor device, in accordance with some embodiments of the present disclosure.

FIGS. 3A to 3G illustrates cross-sectional views of intermediate stages of a method of forming and testing a semiconductor device, in accordance with some embodiments of the present disclosure.

FIGS. 4A to 4C illustrates cross-sectional views of intermediate stages of a method of forming and testing a semiconductor device, in accordance with some embodiments of the present disclosure.

FIGS. 5A to 5G illustrates cross-sectional views of intermediate stages of a method of forming and testing a semiconductor device, in accordance with some embodiments of the present disclosure.

FIGS. 6A to 6C illustrates cross-sectional views of intermediate stages of a method of forming and testing a semiconductor device, in accordance with some embodiments of the present disclosure.

FIG. 7 illustrates a flow chart illustrating a method of fabricating and testing a semiconductor device, in accordance with some embodiments of the present disclosure.

### DETAILED DESCRIPTION OF THE DISCLOSURE

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Also, the components disclosed herein may be arranged, combined, or configured in ways different from the exemplary embodiments shown herein without departing from the scope of the present disclosure. It is understood that those skilled in the art will be able to devise various equivalents that, although not explicitly described herein, embody the principles of the present invention.

Further, spatially relative terms, such as “beneath,” “below,” “lower,” “above,” “upper” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “substantial” or “substantially” generally mean within 10%, 5%, 1% or 0.5% of a given value or range. Alternatively, the terms “about,” “substantial” or “substantially” mean within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “about,” “substantial” or “substantially.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

As used herein, the term “connected” may be construed as “electrically connected,” and the term “coupled” may also be construed as “electrically coupled.” “Connected” and “coupled” may also be used to indicate that two or more elements cooperate or interact with each other.

Embodiments of the present disclosure discuss a new semiconductor testing pad structure, a method of forming the same and a testing method using the same. The testing operation is accomplished by a probe card including an array of probing needles and testing circuits coupled to the probing needles. The arrangement of the probing needles, e.g., the sizes of the probing noodles and their pitches, may comply with an industry standard, and the testing pads formed on the semiconductor devices are arranged to be aligned with the probing needles, such that the probe card can be reused across different types of semiconductor devices as long as these semiconductor devices include the testing pads in compliance with the probe card standard. As a result, the testing time and cost can be minimized through the standardized testing environment. However, as the device size of semiconductor devices continues to reduce, the testing pads of the semiconductor devices are also required to reduce in size accordingly in order to be accommodated within the limited surface area of the semiconductor devices. As such, the pitches and sizes of the testing pads may be less than those defined in the existing standardized probe card. Therefore, a probing apparatus with more probing flexibility and greater needle density may be required to fulfill the requirement of the advanced high-density testing pad configurations.

Moreover, when the testing pads are made even closer to each other in order to achieve a lower pad pitch, an effect referred to as inter-pad corruption is found to be detrimental to the integrity of the testing pads. The testing pads may be unintentionally electrically connected to the adjacent testing pads or signal pads due to the ultra-small pitch between the testing pads or between the testing pads and the signal pads. As a result, circuit defects, e.g., short circuit, may be formed between the aluminum-based testing pad and the copper-based signal pad.

To address the abovementioned issues, the present disclosure proposes an improved testing pad structure and testing methods using the improved testing pad structure. The improved testing pad structure can achieve less pad pitches and pad sizes to fulfill the testing requirements of small-size devices, while showing better electrical properties, in which electrical isolation between adjacent testing pads or signal pads are enhanced. The testing task may be performed with a more accurate and efficient manner.

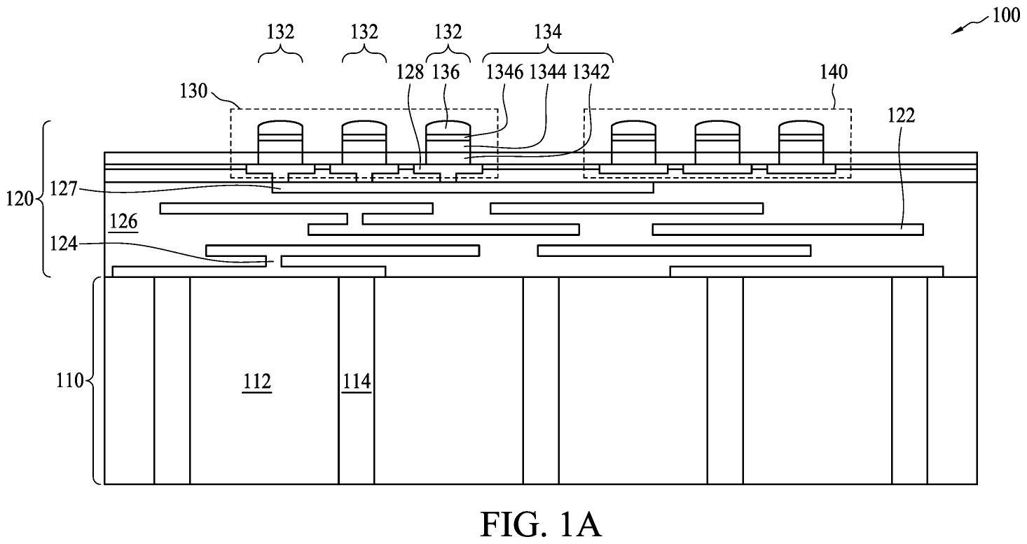

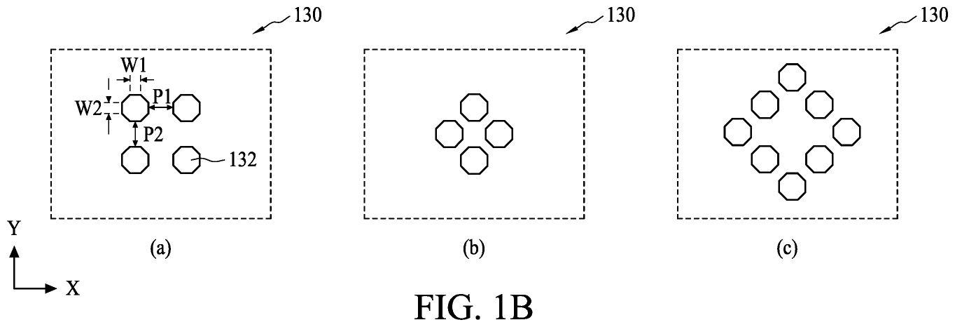

FIG. 1A illustrates a cross-sectional view of a semiconductor device 100, in accordance with some embodiments of the present disclosure. According to some embodiments, the semiconductor device 100 is a package device, a two-dimensional integrated circuit (2D IC), a 2.5D IC, a 3D IC, or other suitable semiconductor devices. As illustrated in FIG. 1A, the semiconductor device 100 includes a substrate layer 110 and an interconnect structure 120. However, other layers or features may also be incorporated into the semiconductor device 100, and the present disclosure is not limited thereto.

According to some embodiments, a substrate 112 is provided or formed as a base material of the substrate layer 110. In some embodiments, the substrate 112 includes a semiconductor material such as bulk silicon. In some embodiments, the substrate 112 includes other semiconductor materials, such as silicon germanium, silicon carbide, gallium arsenide, or the like. According to the present embodiment, the substrate 112 is a P-type semiconductive substrate (acceptor type). According to some other embodiments, an N-type semiconductive substrate (donor type) 112 can be used. Alternatively, the substrate 112 includes another elementary semiconductor, such as germanium; a compound semiconductor including gallium arsenic, gallium phosphide, indium phosphide, indium arsenide, or indium antimonide; an alloy semiconductor including SiGe, GaAsP, AlInAs, AlGaAs, GaInAs, GaInP, or GaInAsP; or combinations thereof. According to yet another embodiment, the substrate 112 includes portions to form a semiconductor-on-insulator (SOI) substrate. In other alternatives, the substrate 112 may include a doped epitaxial layer, a gradient semiconductor layer, and/or a semiconductor layer overlaying another semiconductor layer of a different type, such as a silicon layer on a silicon germanium layer.

According to some embodiments, a plurality of conductive vias 114 are formed in the substrate 112. The conductive vias 114 may include a conductive material, e.g., titanium, titanium nitride, tantalum, tantalum nitride, copper, silver, aluminum, gold, tungsten, combinations thereof, or the like. According to some embodiments, the conductive vias 114 include a single layer or multilayer structure, e.g., a diffusion barrier layer or a seed layer (not separately shown) is deposited on the sidewalls of the conductive vias 114 before a filling layer is formed to fill the spaces of the conductive vias 114. The conductive vias 114 may extend through an entire thickness of the substrate 112, and may be referred to herein as a “through-silicon via” (TSV). The conductive via 114 includes an upper end electrically coupled to the interconnect structure 120 and a lower end exposed from a bottom surface of the substrate layer 110. The conductive vias 114 may electrically connect the interconnect structure 120 to an external circuit or feature, e.g., a bonding bump or a transistor, below the conductive vias 114.

The interconnect structure 120 is configured to electrically couple the components in the substrate layer 110, e.g., the conductive vias 114, to external devices over the interconnect structure 120. According to some embodiments, the interconnect structure 120 may establish redistributed connections for the features within or below the substrate layer 110 for facilitating signal transmission. Thus, the interconnect structure 120 can also be referred to as a “redistribution layer” (RDL). The interconnect structure 120 may have a plurality of metal line layers each including conductive lines 122. The conductive lines 122 in each metal line layer extend along a horizontal direction and are interconnected through adjacent vertical conductive vias or contacts 124 in the respective conductive via layers. The conductive lines 122 and conductive vias 124 may be formed of conductive materials, such as copper, tungsten, aluminum, silver, titanium, tantalum, combinations thereof, or the like. The conductive lines 122 and the conductive vias 124 may be electrically insulated by one or more inter-metal dielectric (IMD) layer 126. The IMD layer 126 may include a dielectric material, e.g., silicon oxide, silicon nitride, silicon carbide, silicon oxynitride, a polymeric material, or the like. The numbers and configurations of metal line layers and metal via layers for the conductive lines 122 or conductive vias 124 can be configured in adaptation to different applications as desired, and the present disclosure is not limited thereto.

According to some embodiments, the interconnect structure 120 includes a topmost metal line layer arranged around the top portion of the interconnect structure 120. The topmost metal line layer includes a plurality of conductive lines 127 electrically connected to the underlying metal line layers or metal via layers of the interconnect structure 120. The conductive lines 127 may include a material the same as or different from that of the conductive lines 122 or the conductive vias 124 in the lower metal line layers or metal via layers. For example, the conductive lines 122 or the conductive vias 124 are typically formed of copper (Cu) for its desirable low resistance performance. The conductive lines 128 may be formed of an aluminum-based material, such as aluminum (Al) or aluminum-copper (Al—Cu). The aluminum-based material may provide better protection against oxidation at a cost of higher resistance than copper.

Referring to FIG. 1A, the interconnect structure 120 further includes an exemplary testing pad unit 130 and an exemplary signal pad unit 140 electrically coupled to the underlying conductive lines 127 through intervening conductive pads 128. The signal pad unit 140 may be configured as signal pads used for transmitting or receiving electrical signals of the semiconductor device 100 to perform tasks of the semiconductor device 100 when the semiconductor device 100 is operated during a working phase. The testing pad unit 130 is configured as testing pads for transmitting or receiving electrical signals to test the signal integrity of the semiconductor device 100 during a testing phase of manufacturing the semiconductor device 100. The number of the signal pad units 140 or the number of the testing pad units 130 is determined according to a design specification, and the present disclosure is not limited thereto.

Each of the signal pad unit 140 and the testing pad unit 130 is formed of a plurality of pad assemblies 132. Each of the pad assemblies 132 includes a conductive pad 128, a conductive plug stack 134, and a conductive bump 136. According to some embodiments, the conductive plug stack 134 is omitted, and the conductive bump 136 is in direct contact with the conductive pad 128. The multiple pad assemblies 132 are electrically connected together and can be seen as fan-out pad elements of a same signal pad unit 140 or the testing pad unit 130. Further, the same components across different pad assemblies 132 of the same signal pad units 140 or the testing pad units 130 can be seen as an integrated structure. For example, the plurality of conductive pads 128 of the same signal pad unit 140 or testing pad unit 130 can be regarded collectively as a conductive pad structure of the respective signal pad unit 140 or testing pad unit 130. Similarly, the conductive plug stacks 134 of the same signal pad unit 140 or testing pad unit 130 can be regarded collectively as a conductive plug structure of the respective signal pad unit 140 or testing pad unit 130. Further, the conductive bumps 136 of the same signal pad unit 140 or testing pad unit 130 can be regarded collectively as a conductive bump structure of the respective signal pad unit 140 or testing pad unit 130.

According to some embodiments, each conductive plug stack 134 includes a first conductive layer 1342, a second conductive layer 1344 and a third conductive layer 1346 formed over one another as a stack. The conductive plug stack 134 may enhance the electrical properties of the respective pad assembly 132 and prolong the lifetime of the respective pad assembly 132. According to some embodiments, the second conductive layer 1344 includes a material different from the first or third conductive layer 1342, 1346. For example, the first conductive layer 1342 and the third conductive layer 1346 include copper, while the second conductive layer 1344 includes nickel. According to some embodiments, the conductive plug stack 134 is absent from the pad assembly 132 and therefore the conductive bump 136 can be formed directly on the conductive pad 128.

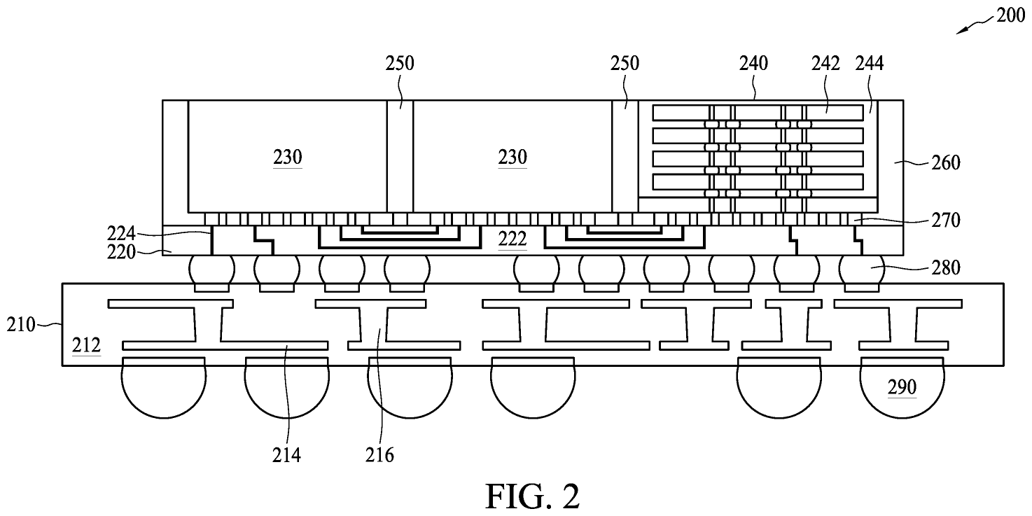

FIG. 1B illustrates top views of the signal pad unit 140 or the testing pad unit 130 of the semiconductor device 100 shown in FIG. 2A, in accordance with some embodiments of the present disclosure. Referring to subfigure (a) of FIG. 1B, the signal pad unit 140 or the testing pad unit 130 includes four pad assemblies 132 that are electrically interconnected for transmitting or receiving the same signal. The four pad assemblies 132 may be spaced apart from each other and distributed in a ring shape, like a square ring shape or a rectangular ring shape from a top-view perspective. Each pad assembly 132 or each conductive bump 136 may have a circular shape, a quadrilateral shape, a hexagonal shape, an octagonal shape, or other suitable shapes from a top-view perspective. According to some embodiments, the four pad assemblies 132 are located in the 45°, 135°, 225° and 315°, respectively, of the ring shape, with the x-axis direction serving as the reference (0°) angle.

The arrangement of the multiple pad assemblies 132 of the signal pad unit 140 or the testing pad unit 130 provides advantages. According to some embodiments, on the one hand, the contact area between the probing needle and the probing pads of the semiconductor device 100 should be sufficiently large to ensure proper engagement during probing. On the other hand, the area of the probing surface of the signal pad unit 140 or the testing pad unit 130 is constrained for comply with a process-friendly manufacturing process. Based on the foregoing, it would be advantageous to provide the signal pad unit 140 or the testing pad unit 130 with a plurality of pad assemblies 132 to generate a collective pad structure with a collective contact area commensurate with the contact area of the probing needle, while the sizes and pitches of conductive pads in the signal pad unit 140 or the testing pad unit 130 can be compliant with the manufacturing requirement.

Referring to subfigure (b) of FIG. 1B, the signal pad unit 140 or the testing pad unit 130 includes four pad assemblies 132. The four pad assemblies 132 may be spaced apart from each other and form a ring shape, a square shape or a rectangular shape. Different from the layout shown in the subfigure (a) of FIG. 1B, the layout of the pad assemblies 132 shown in the subfigure (b) is arranged such that the four pad assemblies 132 are located in the 0°, 90°, 180° and 270°, respectively, of the ring shape. In other words, the layout of the pad assemblies 132 shown in the subfigure (b) can be seen as a rotated version of the layout of the pad assemblies 132 shown in the subfigure (a) by 45°.

Referring to subfigure (c) of FIG. 1B, the signal pad unit 140 or the testing pad unit 130 includes eight pad assemblies 132. The eight pad assemblies 132 may be spaced apart from each other and form a ring shape, a square shape or a rectangular shape.

According to some embodiments, each pad assembly 132 has a width W1 in a range between about 30 μm and about 80 μm, e.g., 55 μm. Further, each pad assembly 132 has a length W2 in a range between about 30 μm and about 80 μm, e.g., 55 μm. According to some embodiments, a first pitch P1 of the pad assemblies 132 measured in the X-axis is in a range between about 10 μm and about 40 μm, e.g., 25 μm. Further, According to some embodiments, a second pitch P2 of the pad assemblies 132 measured in the Y-axis is in a range between about 10 μm and about 40 μm, e.g., 25 μm. The layouts of the pad assemblies 132 shown in the subfigures (a), (b) and (c) above are for illustrative purposes. Other numbers and the layouts of the pad assemblies 132 are also within the contemplated scope of the present disclosure.

During a testing operation, the plurality of pad assemblies 132 of the testing pad unit 130 are configured to communicate with the same probing needle. According to some embodiments, the probing needle has a size or width between about one and about five times of the width W1 or length W2 of the pad assembly 132 to ensure the probing needle can contact most, if not all, of the pad assemblies 132. When the probing needle is moved close to the semiconductor device 100 and finally comes into contact with the testing pad unit 130, the probing needle would come into contact with all or part of the pad assemblies 132.

FIG. 2 illustrates a cross-sectional view of a semiconductor device 200, in accordance with some embodiments of the present disclosure. According to some embodiments, the semiconductor device 200 is a package device, a 2D integrated circuit (IC), a 2.5D IC, a 3D IC, or other suitable semiconductor devices. As illustrated in FIG. 2, the semiconductor device 200 includes a substrate layer 210, an interposer device 220, a plurality of first semiconductor die 230, at least one second semiconductor die 240 and a plurality of integrated passive device (IPD) 250. However, other layers or features may also be incorporated into the semiconductor device 200, and the present disclosure is not limited thereto.

According to some embodiments, the substrate layer 210 includes a substrate 212. The substrate 212 may include a material similar to the substrate 112. According to some embodiments, the substrate layer 210 is a printed circuit board (PCB), and the substrate 212 is formed of a laminated structure including a dielectric material, such as glass fabric and epoxy resin. The substrate 210 may further includes a plurality of metal line layers and metal via layers including a plurality of conductive lines 214 and a plurality of conductive vias 216, respectively, insulated by the dielectric material. The materials and configurations of the conductive line layers, conductive via layers of the substrate layer 210 are similar to those of the interconnect layer 120, and these similar features will not be repeated for brevity.

According to some embodiments, the interposer device 220 includes a substrate 222 and a plurality of conductive lines 224. The substrate 222 may include a material similar to the substrate 112. The plurality of conductive lines 224 are configured to electrically couple the substrate layer 210 to the semiconductor devices 230, 240, and the IPDs 250, or electrically couple the semiconductor devices 230, 240, and the IPDs 250. The conductive lines 224 may include a conductive material, e.g., titanium, titanium nitride, tantalum, tantalum nitride, copper, silver, aluminum, gold, tungsten, combinations thereof, or the like.

According to some embodiments, the semiconductor devices 230 is a processor die, an FPGA (field-programmable gate array) die, a network interface die, a MEMS (micro electromechanical system) die, or other suitable dies. According to some embodiments, the semiconductor device 240 is a memory package including a stack of memory dies 242. The semiconductor device 240 may further include a molding material 244 molding the stack of memory dies 242. The molding material 244 may include a dielectric material, e.g., oxide, nitride, a polymeric material, epoxy resin, or the like. According to some embodiments, the IPD 250 is a capacitor die, an inductor die, a resistor die, or the like.

According to some embodiments, the interposer device 220, the semiconductor devices 230, 240 and the IPDs 250 are molded by a molding material 260. The molding material may include a dielectric material, e.g., a polymeric material such as polyimide (PI), polyphenylene sulfide (PPS), Polyetheretherketone (PEEK), polyethersulfone (PES), a molding underfill, an epoxy, a resin, or a combination thereof.

According to some embodiments, the molded the semiconductor devices 230, 240 and the IPDs 250 are bonded to the interposer device 220 through an array of first connectors 270. Similarly, according to some embodiments, the interposer device 220 is bonded to the substrate layer 210 through an array of second connectors 280. Further, according to some embodiments, the substrate layer 210 is bonded to external devices through an array of third connectors 290. The sizes and pitches of the first connectors 270 are less than those of the second connectors 280, and the sizes and pitches of the first connectors 280 are less than those of the second connectors 290. According to some embodiments, the first connectors 270 are referred to as micro-bumps, the second connectors 280 are referred to as C4 (controlled-collapse chip connection) bumps, and the third connectors 290 are referred to BGA (ball grid array) bumps. According to some embodiments, the first connectors 270, second connectors 280 and the third connectors 290 are formed of a solder material. The solder material may be formed of Sn, Pb, Ni, Au, Ag, Cu, Bi, combinations thereof, or mixtures of other electrically conductive material. According to some embodiments, the solder material is formed of tin-based materials, such as SnAg, SnPb, SnAgCu, or the like. In one embodiment, the solder material is a lead-free material. According to some embodiments, at least the first connectors 270 have a configuration similar to the signal pad unit 140 and the testing pad unit 130 shown in FIGS. 1A and 1B.

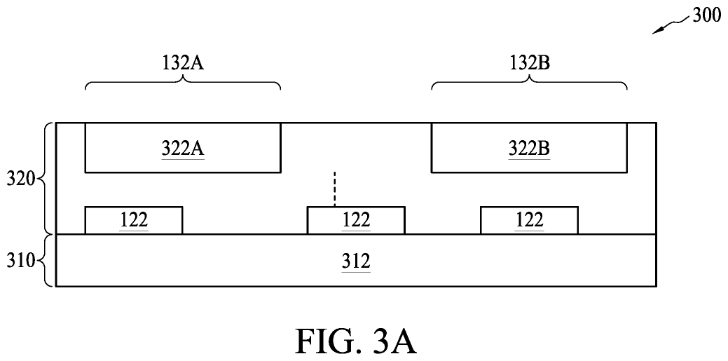

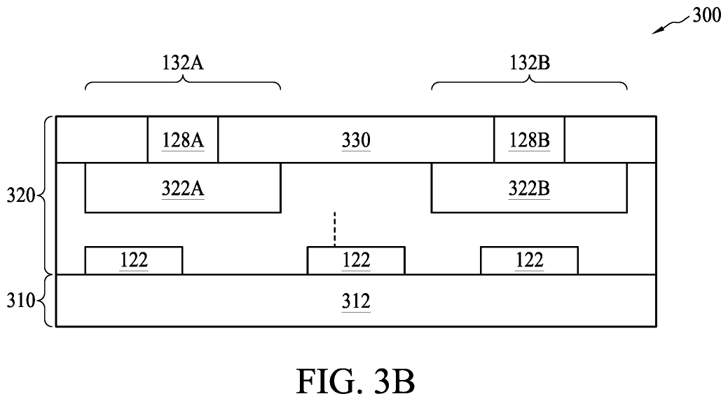

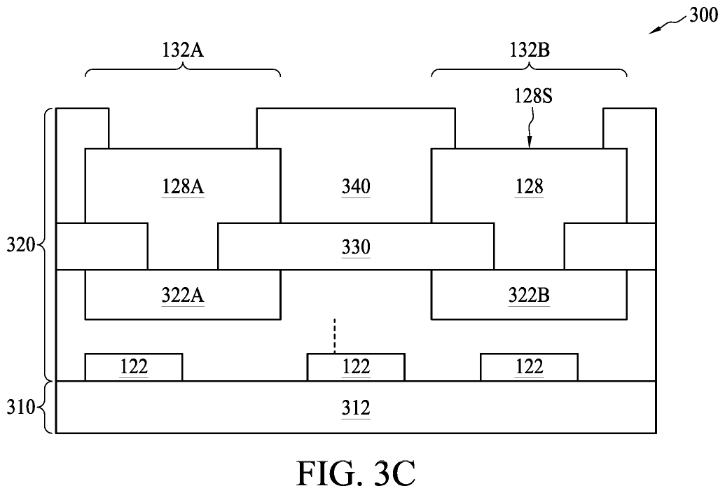

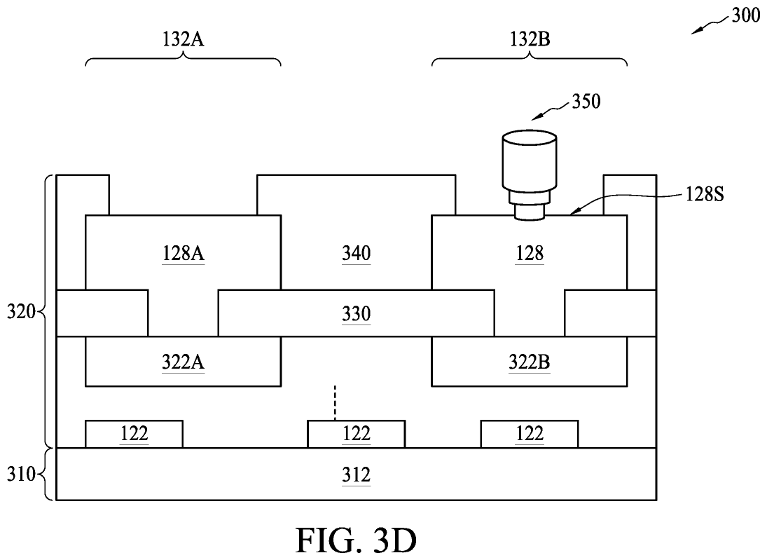

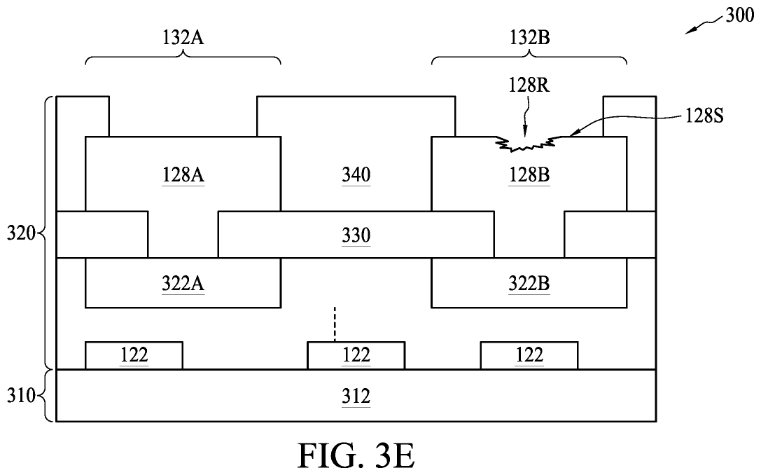

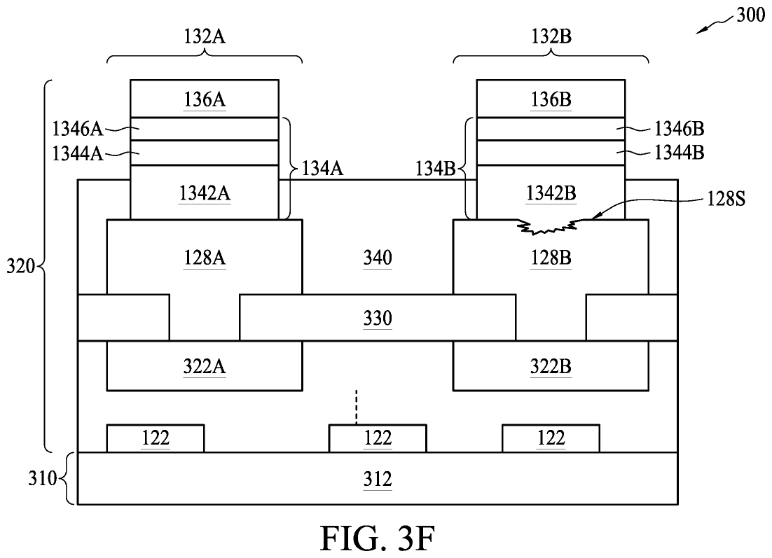

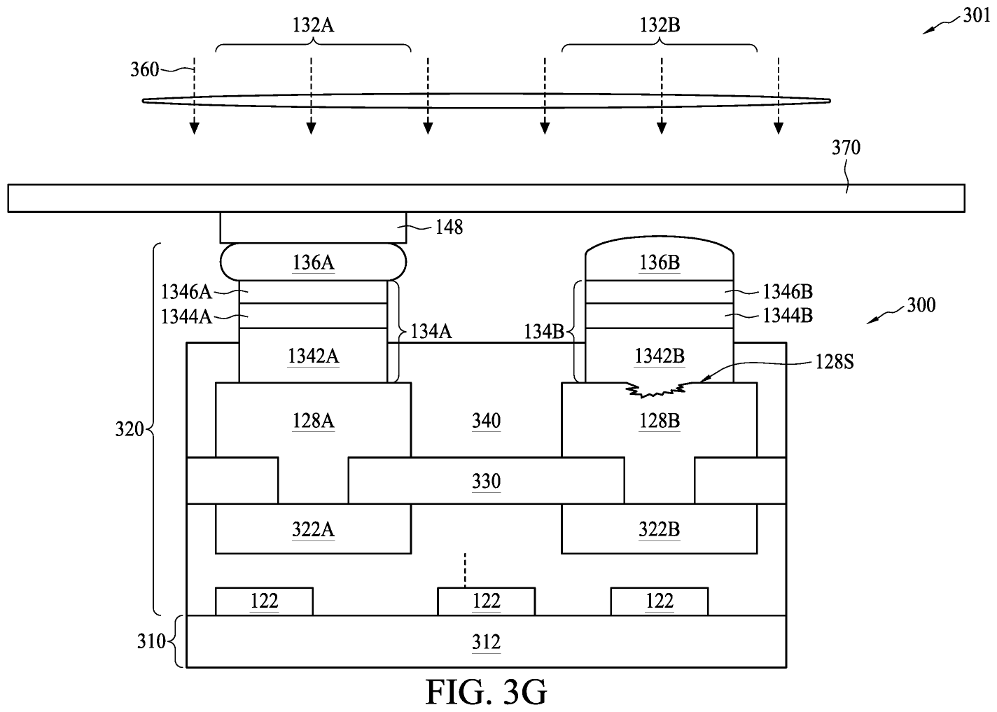

FIGS. 3A to 3G illustrates cross-sectional views of intermediate stages of a method of forming and testing a semiconductor device 300, in accordance with some embodiments of the present disclosure. It should be understood that additional steps can be provided before, during, and after the steps shown in FIGS. 3A to 3G, and some of the steps described below can be replaced or eliminated, for additional embodiments of the method. The order of the steps may be changed. Materials, configurations, dimensions, processes and/or operations the same as or similar to those described with respect to the foregoing embodiments may be employed in the following embodiments, and the detailed explanation thereof may be omitted.

Referring to FIG. 3A, according to some embodiments, the semiconductor device 300 includes a substrate layer 310 and an interconnect structure 320. The interconnect structure 320 includes a first pad assembly 132A and a second pad assembly 132B to represent respective pad assemblies of the signal pad unit 140 and the testing pad unit 130 (not separately shown).

The substrate layer 310 may include a substrate 312 formed of a material similar to that of the substrate 112. According to some embodiments, some semiconductor devices or their components are formed on or within the substrate 312. For example, some conductive features, semiconductive features and dielectric features are formed or patterned on the substrate 112. These components may construct passive devices, e.g., resistors, capacitors, inductors, diodes, fuses, or the like, or active devices, e.g., field-effect transistors (FET), bipolar junction transistors (BJT), planar transistors, fin-type transistors (FinFET), gate-all-around (GAA) transistors, nanosheet transistors, nanowire transistors, or the like.

According to some embodiments, the semiconductor devices or their components are formed or manufactured by known semiconductor manufacturing processes, such as cleaning, lithography, deposition, spread coating, etching, polishing, diffusion, thermal treatment, implantation, bonding, alignment, calibration, and the like.

According to some embodiments, the interconnect structure 320 is formed over and electrically coupled to the substrate layer 310. The interconnect structure 320 may be similar to the interconnect structure 120, and thus most features of the interconnect structure 320 are omitted from FIG. 3A for brevity. FIG. 3A only illustrates a plurality of exemplary conductive lines 122 in a first (bottom) layer of the interconnect structure 320 closest to the substrate layer 310, where the conductive lines 122 represent the plurality of conductive lines and conductive vias of the conductive line layers and conductive via layers, respectively. Further, FIG. 3A illustrates conductive lines 322, e.g., a first conductive line 322A and a second conductive line 322B, in a second to the last (top) layer of the interconnect structure 320 farthest from the substrate layer 310, where the conductive lines 322 represent the plurality of conductive lines in a second to the topmost layer of the conductive line layers. The conductive lines 122 and 322 may include a conductive material, such as copper. The conductive lines 122 and 322 may be formed by deposition, lithography and etching operations.

Referring to FIG. 3B, according to some embodiments, a passivation layer 330 is formed at the topmost layer of the interconnect structure 320 over the conductive lines 322. The passivation layer 330 may be formed of a dielectric material, such as silicon oxide, silicon nitride, silicon carbide, silicon oxynitride, polymeric materials, or the like. According to some embodiments, bottom portions of conductive pads 128, e.g., a first conductive pad 128A and a second conductive pad 128B, are formed in the passivation layer 330. The bottom portions of the conductive pads 128 may include a conductive material, such as copper or aluminum-based material, e.g., aluminum, aluminum copper, or the like. The bottom portions of the conductive pads 128 may be formed by etching trenches in the passivation layer 330, depositing conductive materials in the trenches, and removing excess conductive materials from the surface of the passivation layer 330 to planarize the upper surface of the bottom portions of the conductive pads 128.

Referring to FIG. 3C, according to some embodiments, a passivation layer 340 is formed over the passivation layer 330. The passivation layers 330 and 340 may be collectively referred to as the last (top) layer of the interconnect structure 320. The passivation layer 340 may be formed of a dielectric material, such as silicon oxide, silicon nitride, silicon carbide, silicon oxynitride, polymeric materials, or the like. According to some embodiments, upper portions of the conductive pads 128 are formed in the passivation layer 340 and electrically coupled to the respective bottom portions of the conductive pads 128. The upper portions of the conductive pads 128 may include a conductive material, such as copper or aluminum-based material, e.g., aluminum, aluminum copper, or the like. The upper portions of the conductive pads 128 may be formed by etching trenches in the passivation layer 340 to expose the surfaces of the bottom portions of the conductive pads 128, depositing conductive materials in the trenches, and removing excess conductive materials from the surface of the passivation layer 340 to planarize the upper surface 128S of the upper portions of the conductive pads 128.

According to some embodiments, the passivation layer 340 is further deposited and thickened upwardly to cover the conductive pads 128. According to some embodiments, the passivation layer 340 is patterned to expose the upper surfaces 128S of the conductive pads 128. The patterning operation of the passivation layer 340 may include lithography and etching operations. Through the patterning operation, the upper surfaces 128S are exposed while the sidewalls of the upper portions of the conductive pads 128 are laterally surrounded or covered by the passivation layer 340.

According to some embodiments, the metal line layer where the conductive line 322 resides is regarded the topmost layer of the interconnect structure, and the conductive pad 128 is regarded a conductive pad (either signal pad or testing pad) of the respectively pad assembly 132.

Referring to FIG. 3D, a testing operation is performed on the second conductive pad 128B. According to some embodiments, a probe card (not separately shown) including an array of probe needles are used to perform the testing operation. An exemplary probe needle 350 is shown to contact the upper surface 128S (which is also referred to as a probing surface in the depicted example) of the second conductive pad 128B and transmit the testing input signals or receive the testing response signals. According to some embodiments, each of the testing input signal or the testing response signal may carry testing or response information in terms of its voltage or current level. According to some embodiments, during the testing operation, a testing parameter set is provided to semiconductor device 300 through a testing equipment with the probe needles, in which the probe needles capture a set of corresponding testing measurements, e.g., a current-voltage (I-V) curve and send the testing measurements to a processor for further inspection or analysis. The testing parameter sets may be various depending upon different testing conditions for the targeted applications of the semiconductor device 300. Referring to FIGS. 1B and 3D, since the testing pad unit 130 is constructed by multiple pad assemblies 132B (FIG. 3D only illustrates one pad assembly 132B), the probe needle 350 would be pressed on the surfaces of all or part of the multiple pad assemblies 132B during the testing operation.

FIG. 3E illustrates the cross-sectional view of the semiconductor device 300 after the testing operation is completed. After the probing needle 350 is removed from the second conductive pad 128B, a probing mark 128R caused by the pressing of the probe needle 350 on the upper surface 128S is left on the upper surface 128S. According to some embodiments, the probing mark 128R generates a notch with a pattern of the probing needle 350 on the upper surface 128S of the second conductive pad 128B. Such notch is usually irregular in its depth or pattern, and would damage the surface planarity of the second conductive pad 128B. There may be a higher chance of debris or particles falling off from the notch of the probing mark 128R. Since the first conductive pad 128A is part of the functional signal transmission path, rather than part of the testing signal transmission path, of the semiconductor device 300, no probing would occur to the first conductive pad 128A. Thus, the upper surface of the first conductive pad 128A is kept substantially smooth and notch-free.

Referring to FIG. 3F, in response to a testing result of the testing operation as complying with a testing performance, conductive plug stacks 134, e.g., a first conductive plug stack 134A and a second conductive plug stack 134B, are formed over the respective conductive pads 128, e.g., the first conductive pad 128A and second conductive pad 128B. According to some embodiments, the conductive plug stacks 134 each include a first conductive layer 1342 (including layers 1342A and 1342B), a second conductive layer 1344 (including layers 1344A and 1344B) and a third conductive layer 1346 (including layers 1346A and 1346B) arranged in a stack. The first conductive layer 1342 may be in direct contact with the conductive pad 128. According to some embodiments, the first conductive layer has a material similar to the third material. The material of the first conductive layer 1342 and the third conductive layer 1346 may be different from that of the second conductive layer 1344. For example, the first conductive layer 1342 and the third conductive layer 1346 includes or is formed of copper, while the second conductive layer 1344 includes or is formed of nickel. The conductive plug stacks 134 may provide advantages of providing better protection and allowing for greater lifetime of the respective pad assemblies 132. Further, the second instance 1342B of the first conductive layer 1342 or the second conductive bump 136B (in the absence of the conductive plug stack 134) fills the notch of the probing mark 128R and protects the upper surface 128S from being exposed. The chances of debris or particles falling off the upper surface 128S may be greatly reduced.

Conductive bumps 136, e.g., a first conductive bumps 136A and a second conductive bump 136B, are formed over the respective conductive plug stacks 134, e.g., the first conductive plug stack 134A and second conductive plug stack 134B. The conductive bumps 136 are used as connectors of the semiconductor device 300 for electrically coupling the semiconductor device 300 to the overlying structures or circuits. According to some embodiments, the conductive plug stacks 134 are omitted from the respective pad assemblies 132, and therefore the conductive bumps 136 are formed directly in contact with the underlying conductive pads 128. The material of the conductive bumps 136 may be different from the conductive lines 122, 322 and the conductive plug stacks 134, and may include a solder material, e.g., a lead-free solder.

Referring to FIG. 3G, the semiconductor 300 is bonded to another semiconductor device 370 to form an integrated semiconductor device 301. Although not separately shown, the semiconductor device 370 may include a substrate layer and an interconnect structure in a manner similar to the semiconductor structure 300. The semiconductor structure 370 may further includes a conductive pad 148 configured as a bonding pad. According to some embodiments, the conductive pad 148 includes a material formed of copper, aluminum, aluminum-copper, or the like. During a bonding operation, the semiconductor device 370 is aligned with and moved toward the semiconductor device 300 until the conductive pad 148 engages the first conductive bump 136A. A reflow operation 360 is performed on the semiconductor device 300 to reshape the conductive bumps 136A and 136B into a spherical shape or semispherical shape. The bonding of the conductive bumps 136A to the bonding pad 148 is thus completed.

As illustrated in FIG. 3G, the first pad assembly 132A is part of the functional signal transmission path of the semiconductor device 300 or 301, and is electrically coupled to the semiconductor device 370 through the bonding of the first conductive bump 136A and the conductive pad 148. However, the second pad assembly 132B is part of the testing signal transmission path of the semiconductor device 300, and is not electrically coupled to the semiconductor device 370 during the bonding operation. The pad assembly 132B may be facing and separated from the semiconductor device 370. According to some embodiments, although not separately shown, a molding or encapsulating material may be employed to fill spaces between the semiconductor device 300 and the semiconductor device 370, e.g., the gaps between the first pad assembly 132A, the second pad assembly 132B and the semiconductor device 370.

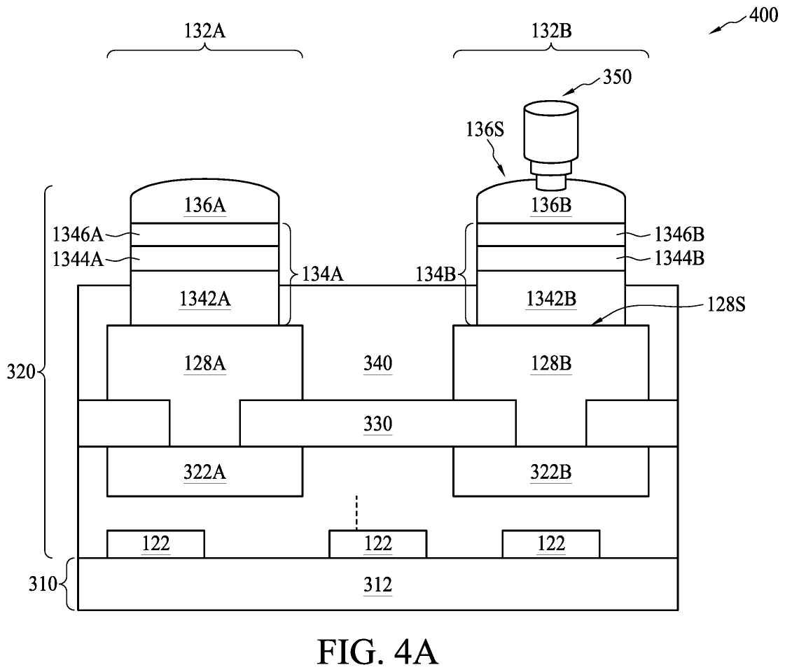

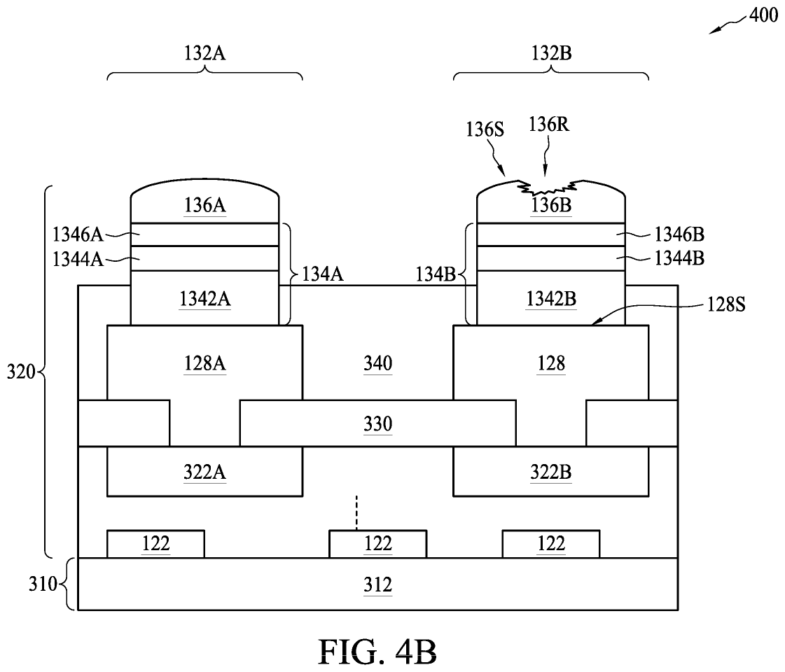

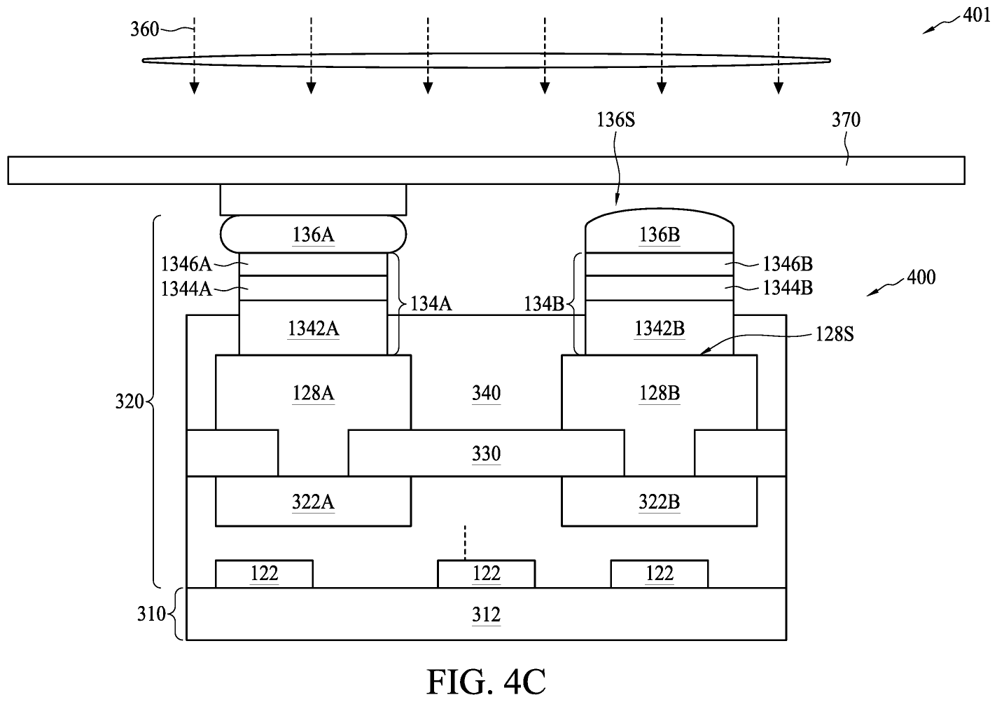

FIGS. 4A to 4C illustrates cross-sectional views of intermediate stages of a method of forming and testing a semiconductor device 400, in accordance with some embodiments of the present disclosure. It should be understood that additional steps can be provided before, during, and after the steps shown in FIGS. 4A to 4C, and some of the steps described below can be replaced or eliminated, for additional embodiments of the method. The order of the steps may be changed. Materials, configurations, dimensions, processes and/or operations the same as or similar to those described with respect to the foregoing embodiments may be employed in the following embodiments, and the detailed explanation thereof may be omitted.

The semiconductor device 400 may be similar to the semiconductor device 300 in many aspects, and these similar features will not be repeated for brevity. FIG. 4A illustrates the semiconductor device 400, which includes the substrate layer 310 and the interconnect layer 320. The main parts of the manufacturing process of the semiconductor device 400 can be found by referring to the intermediate stages shown in FIGS. 3A to 3C and 3F. The difference between the method shown in FIGS. 3A to 3G and that shown in FIGS. 4A to 4C lies in that, in the method shown in FIGS. 4A to 4C, the conductive plug stacks 134 and the conductive bumps 136 are formed prior the testing operation. As illustrated in FIG. 4A, during the testing operation, the probe needle 350 engaged the second conductive bump 136B instead of the conductive pad 128B. Further, according to some embodiments, the reflow operation to reshape the conductive bumps 136A and 136B is performed prior to the testing operation. According to some embodiments, since the testing operation is not performed on the second conductive pad 128B, the upper surface of the conductive pad 128B is kept substantially smooth and notch-free.

Referring to FIG. 4B, after the probing needle 350 is removed from the second conductive bump 136B, a probing mark 136R caused by the pressing of the probe needle 350 on the upper surface 136S (which is also referred to as the probing surface in the depicted example) of the second conductive bump 136B is left on the upper surface. According to some embodiments, the probing mark 136R generates a notch with a pattern of the probing needle 350 on the upper surface 136S. Such notch is usually irregular in its depth or pattern, and would damage the surface smoothness of the second conductive bump 136B. There may be a higher chance of debris or particles falling off from the notch of the probing mark 136R. Since the first conductive bump 136A is part of the functional signal transmission path, rather than part of the testing signal transmission path, of the semiconductor device 400, no probing would occur to the first conductive bump 136A. Thus, the upper surface of the first conductive bump 136A is kept substantially smooth and notch-free.

Referring to FIG. 4C, in response to a testing result of the testing operation as complying with a testing performance, the semiconductor 400 is bonded to the semiconductor device 370 to form an integrated semiconductor device 401. During a bonding operation, the semiconductor device 370 is aligned with and moved toward the semiconductor device 400 until the conductive pad 148 engages the first conductive bump 136A. A reflow operation 360 is performed on the semiconductor device 401 to reshape the conductive bumps 136A and 136B into a spherical shape or semispherical shape. The bonding of the first conductive bump 136A to the bonding pad 148 is thus completed. As a result, the notch of the probing mark 136R that is left on the second conductive bump 136B is removed by the reflow operation, and the smooth upper surface 136S of the second conductive bump 136B is recovered. Therefore, the chances of debris or particles falling off from the upper surface 136S of the second conductive bump 136B may be greatly reduced.

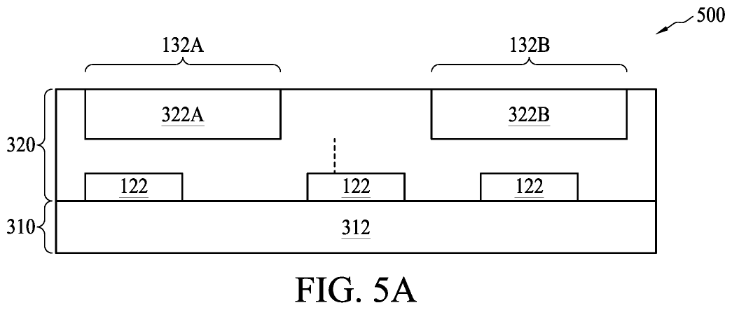

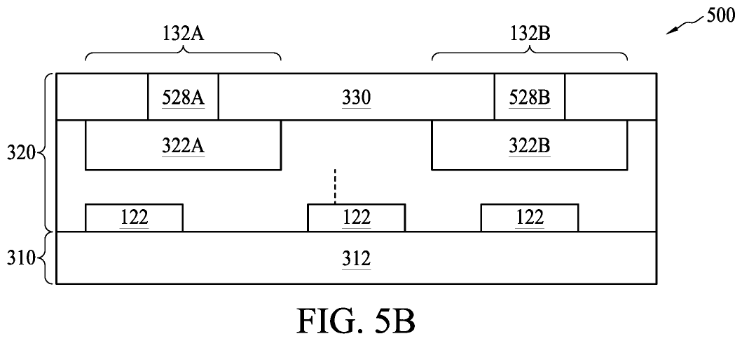

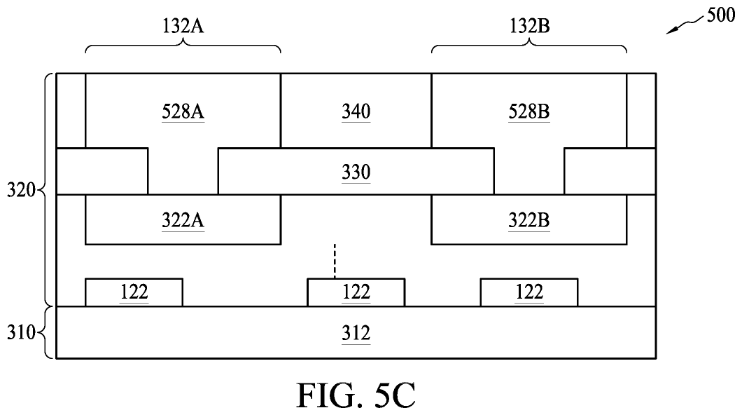

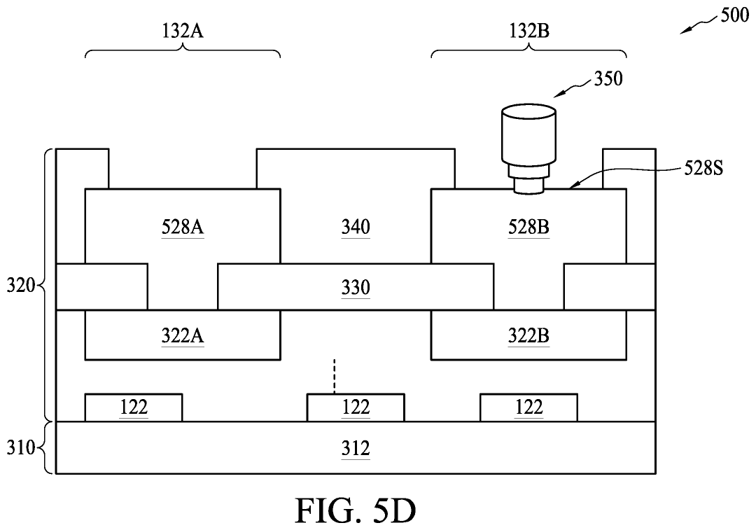

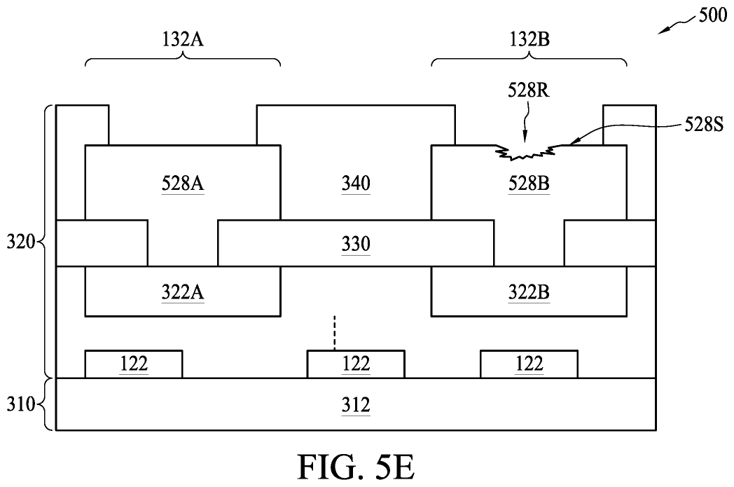

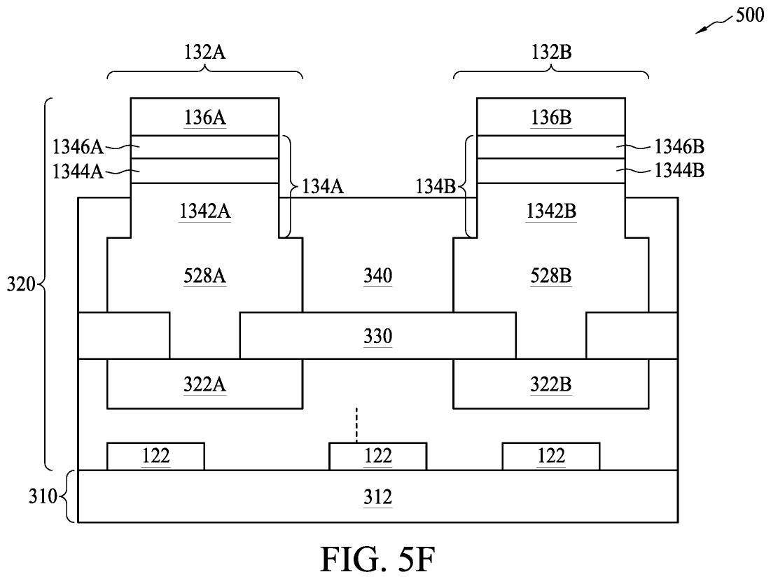

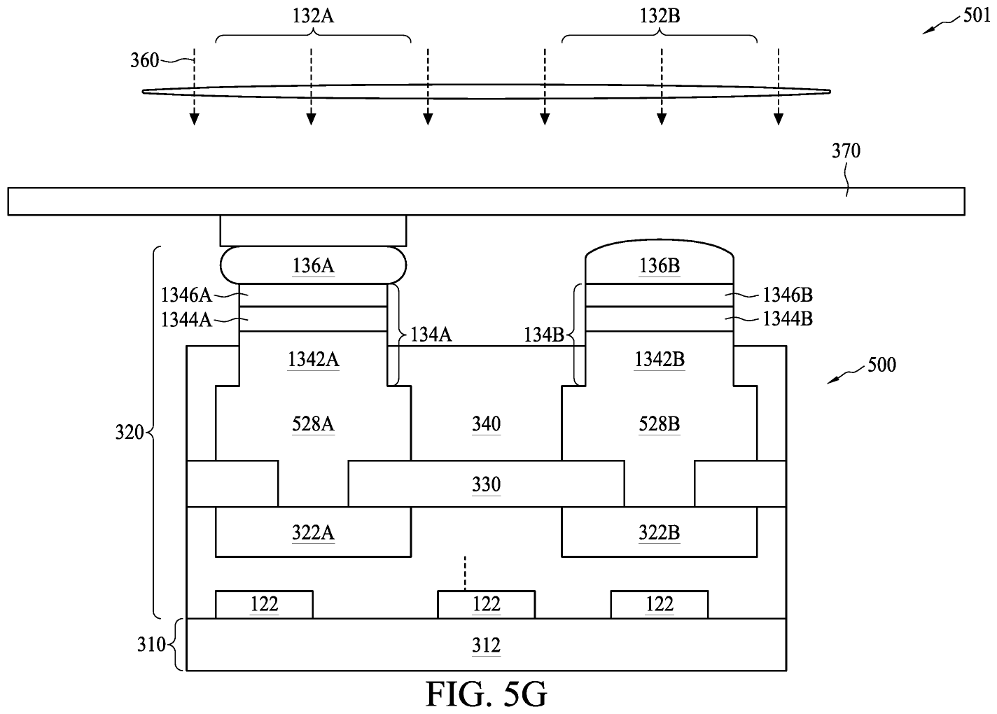

FIGS. 5A to 5G illustrates cross-sectional views of intermediate stages of a method of forming and testing a semiconductor device, in accordance with some embodiments of the present disclosure. It should be understood that additional steps can be provided before, during, and after the steps shown in FIGS. 5A to 5G, and some of the steps described below can be replaced or eliminated, for additional embodiments of the method. The order of the steps may be changed. Materials, configurations, dimensions, processes and/or operations the same as or similar to those described with respect to the foregoing embodiments may be employed in the following embodiments.

The semiconductor device 500 may be similar to the semiconductor device 300 in many aspects, and these similar features will not be repeated for brevity. Further, the steps shown in each of FIGS. 3A to 3G correspond to those shown in FIGS. 5A to 5G, respectively. Therefore, the method shown in FIGS. 5A to 5G can be seen as a mirrored version of that shown in FIGS. 3A to 3G. The main difference between the method shown in FIGS. 5A to 5G and that shown in FIGS. 3A to 3G lies in that the conductive pads 128 are replaced with conductive pads 528, e.g., a first conductive pad 528A and a second conductive pad 528B. Therefore, after a testing operation shown in FIG. 5D, a probing mark 528R is left on an upper surface 528S (which is also referred to as the probing surface in the depicted example) of the second conductive pad 528B as shown in FIG. 5E, in a manner similar to the step shown with reference to FIG. 3E. The conductive pads 528 have electrical resistance less than that of the conductive pads 128, and therefore are more suitable for the functional signal transmission path of the semiconductor device 500. According to some embodiments, the material of the conductive pads 128 is an aluminum-based material, while the material of the conductive pads 528 is a copper-based material, e.g., copper. As a result, the overall resistance of the signal paths of the semiconductor device 500 can be further reduced. According to some embodiments, the conductive pads 528 have a material the same as that of the overlying first conductive layers 1342. Therefore, after the deposition of the first conductive layer 1342 on the conductive pads 528, the notch of the probing mark 528R may be eliminated and the trace of the notch may not be visible.

In response to a testing result of the testing operation as complying with a testing performance, the semiconductor device 500 is bonded to the semiconductor device 370 to form a semiconductor device 501, as illustrated in FIG. 5G, in a manner similar to the step shown with reference to FIG. 3G.

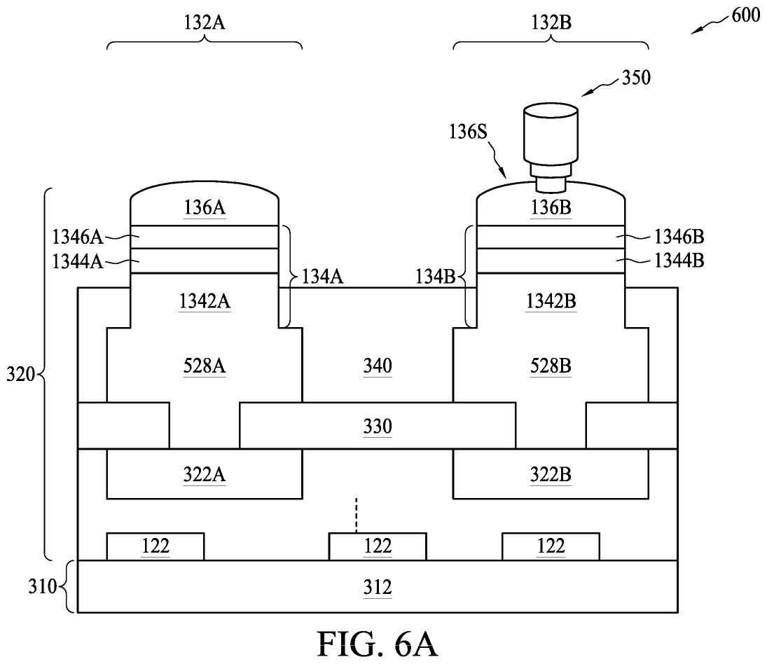

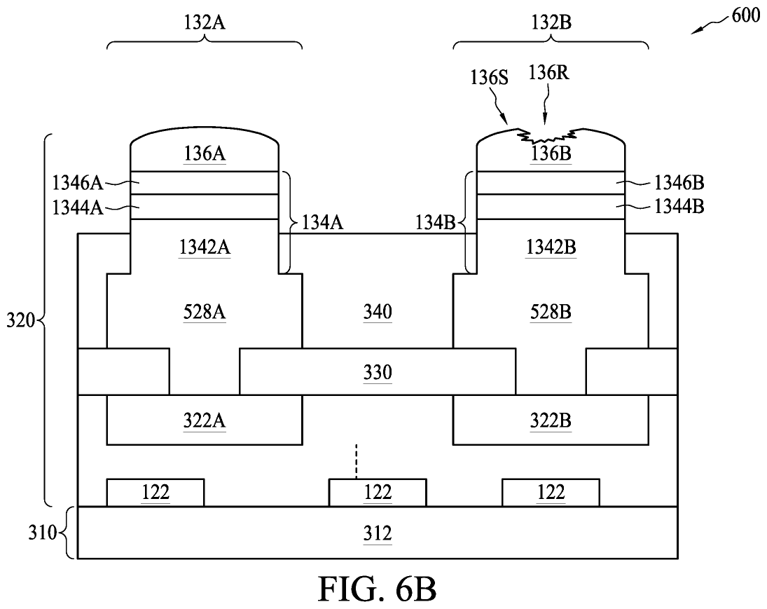

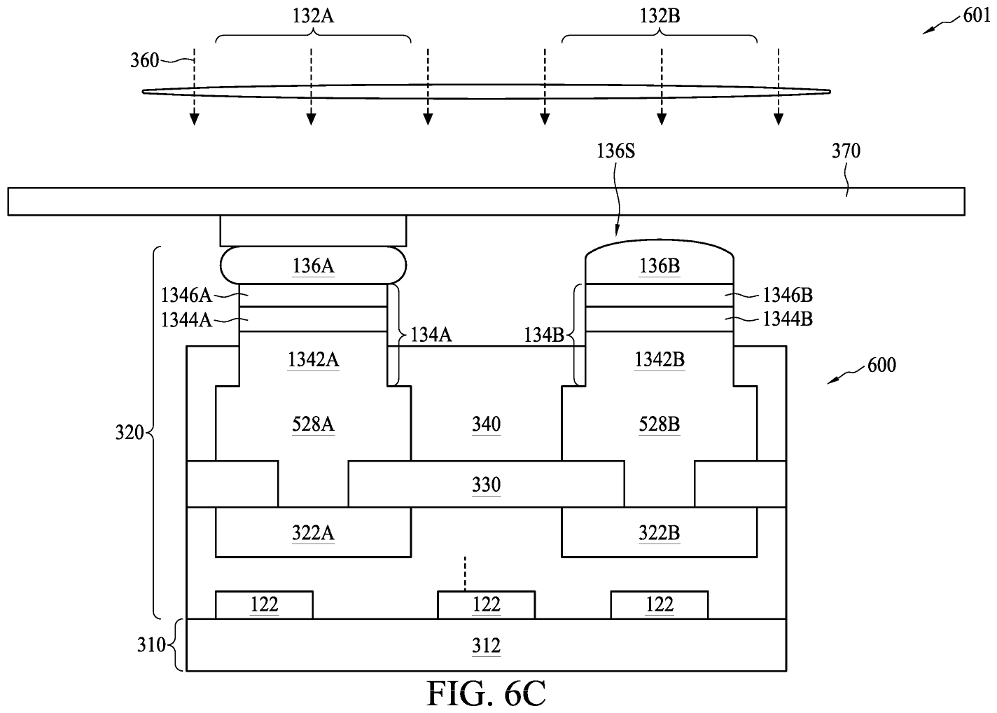

FIGS. 6A to 6C illustrates cross-sectional views of intermediate stages of a method of forming and testing a semiconductor device 600, in accordance with some embodiments of the present disclosure. It should be understood that additional steps can be provided before, during, and after the steps shown in FIGS. 6A to 6C, and some of the steps described below can be replaced or eliminated, for additional embodiments of the method. The order of the steps may be changed. Materials, configurations, dimensions, processes and/or operations the same as or similar to those described with respect to the foregoing embodiments may be employed in the following embodiments.

The semiconductor device 600 may be similar to the semiconductor device 400 in many aspects, and these similar features will not be repeated for brevity. Further, the steps shown in each of FIGS. 4A to 4C correspond to those shown in FIGS. 6A to 6C, respectively. Therefore, the method shown in FIGS. 6A to 6C can be seen as a mirrored version of that shown in FIGS. 4A to 4C. The main difference between the method shown in FIGS. 6A to 6C and that shown in FIGS. 4A to 4C lies in that the conductive pads 128 are replaced with the conductive pads 528, e.g., the first conductive pad 528A and the second conductive pad 528B. The conductive pads 528 have electrical resistance less than that of the conductive pads 128, and therefore are more suitable for the functional signal transmission path of the semiconductor device 600. As a result, the overall resistance of the signal paths of the semiconductor 600 can be further reduced. According to some embodiments, the conductive pads 528 have a material the same as that of the overlying first conductive layers 1342. After a testing operation shown in FIG. 6A, a probing mark 136R is left on an upper surface 136S of the second conductive bump 136B, as shown in FIG. 6A, in a manner similar to the step shown with reference to FIG. 4A. In response to a testing result of the testing operation as complying with a testing performance, the semiconductor 600 is bonded to the semiconductor device 370 to form a semiconductor device 601 as illustrated in FIG. 6C, in a manner similar to the step shown with reference to FIG. 4C. After the reflow operation, the notch of the probing mark 136R may be eliminated and the trace of the notch may not be visible. Therefore, the chances of debris or particles falling off from the upper surface 136S of the second conductive bump 136B may be greatly reduced.

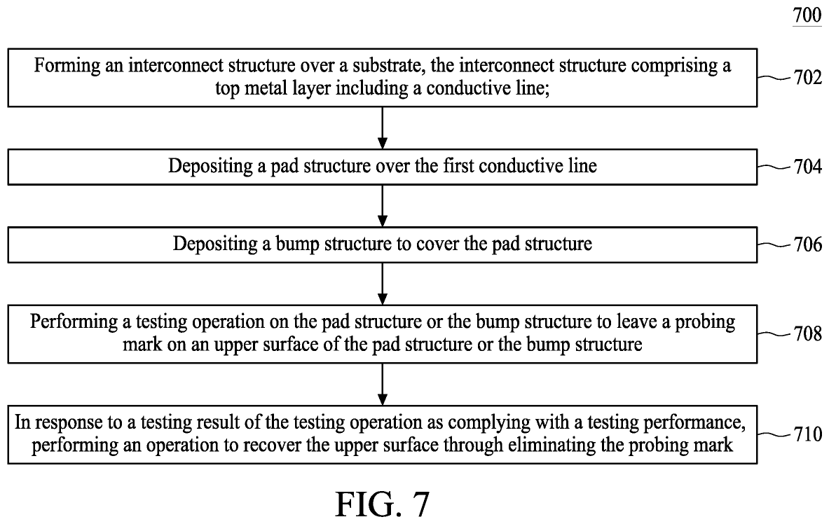

FIG. 7 illustrates a flow chart illustrating a method 700 of fabricating and testing a semiconductor device, in accordance with some embodiments of the present disclosure. It should be understood that additional steps can be provided before, during, and after the steps shown in FIG. 7, and some of the steps described below can be replaced or eliminated, for additional embodiments of the method. The order of the steps may be changed.

At step 702, an interconnect structure, e.g., the interconnect structure 320, is formed over a substrate, e.g., the substrate 312. The interconnect structure includes a top metal layer including a conductive line, e.g., the conductive lines 322.

At step 704, a pad structure, e.g., the pad structure including the conductive pads 128 or 528, is deposited over the first conductive line.

At step 706, a bump structure, e.g., the bump structure including the conductive bumps 136, is deposited to cover the pad structure.

At step 708, a testing operation is performed on the pad structure or the bump structure to leave a probing mark, e.g., the probing mark 128R, 528R or 136R, on an upper surface of the pad structure or the bump structure.

At step 710, in response to a testing result of the testing operation as complying with a testing performance, an operation, e.g., a reflow operation, is performed to recover the upper surface through eliminating the probing mark.

In accordance with one embodiment of the present disclosure, a method includes: forming an interconnect structure over a first substrate, the interconnect structure including a top metal layer including a conductive line; depositing a pad structure over the first conductive line; depositing a first bump structure a to cover the pad structure; performing a testing operation on at least one of the pad structure and the first bump structure to leave a probing mark on an upper surface of at least one of the pad structure and the first bump structure; and in response to a testing result of the testing operation as complying with a testing performance, performing an operation to recover the upper surface through eliminating the probing mark.

In accordance with one embodiment of the present disclosure, a method includes: forming a first interconnect structure over a first substrate, the first interconnect structure including a top metal layer including a first conductive line and a second conductive line; depositing a first conductive pad and a second conductive pad over the first conductive line and the second conductive line, respectively, wherein the first conductive pad is configured as a signal pad, and the second conductive pad is configured as a testing pad; providing a first conductive bump and a second conductive bump to cover the first conductive pad and the second conductive bump, respectively; performing a testing operation on the second conductive pad or the second conductive bump to leave a probing mark on a surface of the respective second conductive pad or the second conductive bump; and in response to a testing result of the testing operation as complying with a testing performance, bonding the first substrate to a second substrate through joining the first conductive bump to a third conductive pad of the second substrate, wherein the second conductive bump is left spaced apart from the second substrate after the bonding.

In some embodiments, a semiconductor device includes an interconnect structure over a first substrate, the interconnect structure having a top metal layer including a first conductive line; a first pad structure arranged over the first conductive line and including a plurality of first conductive pads connected to the first conductive line, the first conductive pads configured as testing pads and formed of a material different from the first conductive line, wherein at least one of the testing pads has a probing mark on a surface thereof; and a first bump structure covering the surface of the pad structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method comprising:
forming an interconnect structure over a first substrate, the interconnect structure comprising a top metal layer including a first conductive line;
depositing a pad structure over the first conductive line;
depositing a first bump structure to cover the pad structure;
performing a testing operation on at least one of the pad structure and the first bump structure to leave a probing mark on an upper surface of the at least one of the pad structure and the first bump structure; and
in response to a testing result of the testing operation as complying with a testing performance, performing an operation to recover the upper surface through eliminating the probing mark.

2. The method of claim 1, wherein the pad structure includes a plurality of conductive pads connected to the first conductive line and exposed through the interconnect structure.

3. The method of claim 2, wherein the plurality of conductive pads are spaced apart from each other and distributed in a ring shape.

4. The method of claim 1, wherein the performing of the testing operation comprises causing a probing needle to contact the pad structure and leave the probing mark on the upper surface of the pad structure.

5. The method of claim 4, wherein the performing of the operation to eliminate the probing mark comprises forming a conductive plug structure to cover the probing mark.

6. The method of claim 5, wherein the conductive plug structure comprises a first conductive layer directly over the pad structure, and the pad structure is formed of a material same as the first conductive layer.

7. The method of claim 1, wherein the performing of the testing operation comprises causing a probing needle to contact the first bump structure and leave the probing mark on the upper surface of the first bump structure.

8. The method of claim 7, wherein the performing of the operation to eliminate the probing mark comprises performing a reflow operation on the first bump structure to recover the upper surface of the first bump structure.

9. The method of claim 8, wherein the operation to eliminate the probing mark further comprises performing a bonding operation to bond a second bump structure to a second substrate while keeping the first bump structure spaced apart from the second substrate.

10. The method of claim 1, wherein the first bump structure comprises a solder material.

11. The method of claim 1, wherein the pad structure comprises aluminum.

12. The method of claim 1, wherein the first bump structure is in direct contact with the pad structure.

13. A method comprising:
forming a first interconnect structure over a first substrate, the first interconnect structure comprising a top metal layer including a first conductive line and a second conductive line;
depositing a first conductive pad and a second conductive pad over the first conductive line and the second conductive line, respectively, wherein the first conductive pad is configured as a signal pad, and the second conductive pad is configured as a testing pad;
providing a first conductive bump and a second conductive bump to cover the first conductive pad and the second conductive bump, respectively;
performing a testing operation on the second conductive pad or the second conductive bump to leave a probing mark on a surface of the respective second conductive pad or the second conductive bump; and
in response to a testing result of the testing operation as complying with a testing performance, bonding the first substrate to a second substrate through joining the first conductive bump to a third conductive pad of the second substrate, wherein the second conductive bump is left spaced apart from the second substrate after the bonding.

14. The method of claim 13, wherein the first conductive pad and the second conductive pad are formed of an aluminum-based material, and the testing operation is performed on the first conductive bump and the second conductive bump such that the probing mark is left on an upper surface of the second conductive bump.

15. The method of claim 14, further comprising performing a reflow operation on the first conductive bump and the second conductive bump subsequent to the testing operation prior to the bonding.

16. The method of claim 13, wherein the first conductive pad and the second conductive pad are formed of copper, and the testing operation is performed on the second conductive pad such that the probing mark is left on an upper surface of the second conductive pad.

17. The method of claim 16, further comprising depositing a first conductive plug stack and a second conductive plug stack on the first conductive pad and the second conductive pad, respectively, to eliminate the probing mark on the second conductive pad.

18. A semiconductor device, comprising:
an interconnect structure over a first substrate, the interconnect structure comprising a top metal layer including a first conductive line;
a first pad structure arranged over the first conductive line and comprising a plurality of first conductive pads connected to the first conductive line, the first conductive pads configured as testing pads and formed of a material different from the first conductive line, wherein at least one of the first conductive pads has a probing mark on a surface thereof; and
a first bump structure covering the surface of the first pad structure.

19. The semiconductor device of claim 18, wherein the first bump structure comprises a plurality of conductive bumps formed of a solder material.

20. The semiconductor device of claim 18, wherein the interconnect structure further comprises a second bump structure bonded to a second substrate, wherein the first bump structure is spaced apart from the second substrate.
